(19) United States
(12) Patent Application Publication
(10) Pub. No.: US 2011/0205372 A1
(43) Pub. Date: Aug. 25, 2011

(54) Electronic device and method of use

(76) Inventor: Ivan Miramontes, Fontana, CA (US)

(21) Appl. No.: 12/930,823

(22) Filed: Jan. 15, 2011

Related U.S. Application Data
(60) Provisional application No. 61/338,826, filed on Feb. 25, 2010.

(51) Int. Cl. H04N 5/225; H05K 7/00; G06F 1/16; G06F 3/041; G06F 3/02

(52) U.S. Cl. 348/207.1; 361/679.01; 361/679.27; 345/173; 345/168; 348/E05.031

(57) ABSTRACT

An electronic device includes a base to which is rotatably connected a tilting member. The base has a input area and the tilting member has a screen. The tilting member is selectively rotatably positionable to (1) a closed position parallel to the base, and (2) an open position upwardly angled away from the base. In the open position the electronic device can be placed on a support surface wherein the rear surface alone of the base supports the tilting member.

### CROSS REFERENCE TO RELATED APPLICATION

This application claims the filing benefit under 35 U.S.C. §119(e) of U.S. Provisional Application No. 61/338,826 filed Feb. 25, 2010, which is hereby incorporated by reference.

### TECHNICAL FIELD

The present invention pertains generally to electronic devices, and more particularly to a hand holdable electronic device which can operate in both closed and open positions.

### BACKGROUND OF THE INVENTION

The problem with today's hand held slate-shaped devices, such as tablet computers and e-readers is that it takes both hands to operate the device. Sometimes one hand is used to hold the device, while the other hand manipulates the touchscreen and/or control buttons. In other instances, the device is laid flat on a work surface, such as a desk or table when used: this factor often causes the user to repeatedly lean over to glance over the device and/or grab and tilt the device towards the user as it lays on the flat surface. For extended viewing or reading or when both hands are not available to hold and operate the device, such as when the user is at a coffee table having breakfast, a hands-free use is more desirable. Device manufactures have attempted to solve this problem by integrating a “kick stand” that open out of the back of the device, allowing the user to prop it up on a flat surface. Another solution is a docking station which allows the device to dock and stand in an upright immobile position. While the kick stand concept is useful because it's built into the device, the docking station is inconvenient and cumbersome to carry along as an extra travel accessory. The problem with these two “erect” device positions is trying to hand type on the soft/hard keyboard and navigate without getting tired or injuring the user's wrists. Hence, it would be desirable to make the device more comfortable and ergonomic to use while reducing the tendency to be tiresome and cause injury.

### BRIEF SUMMARY OF THE INVENTION

The present invention is directed to a portable electronic device such as an e-reader, a tablet computer (Apples IPad®), a MID's (Mobile Internet Device), and the like, which can operate in both closed and open positions. In the closed position the electronic device is typically held in the hand of the user. In the open position the electronic device can be placed upon a support surface and used like a conventional laptop computer. In an embodiment of the invention, the electronic device has two display screens, a larger upper screen and a smaller lower screen.

In a handheld embodiment the device has two touch screens—a large top primary display and a small bottom secondary display. Both screens seamlessly communicate with each other. In an embodiment, the bottom screen primarily functions as a complimentary navigating and text entry system.

In a hands free or table top embodiment the device is laid flat on a work surface, such as a table or desk or on the lap of the user. Then the top display is tilted towards the user at a convenient viewing angle. The long body of the device provides a stable support platform even when the large screen is tilted toward the user. In an alternate embodiment, the bottom screen can be substituted with a hard button keyboard. In yet another embodiment, a wirelessly bluetooth or USB cord keyboard can compliment the device and used as a double up to a traditional PC.

In accordance with an embodiment of the invention, an electronic device includes a base having an input area and a rear surface. A tilting member having a display screen is rotationally connected to the base. The tilting member is selectively rotatably positionable to (1) a closed position parallel to the base, and (2) an open position upwardly angled away from the base. In the open position the base's rear surface alone supports the tilting member and prevents the electronic device from tipping over—a kick stand or other ancillary supporting device is not required.

In accordance with another embodiment, when the tilting member is in the closed position, the input area and the screen reside in side-by-side coplanar relationship.

In accordance with another embodiment, the tilting member has a first side and an opposite second side. A screen is disposed on the first side of the tilting member, and a rear-facing camera is disposed on the second side of the tilting member. The base has an aperture so that when the tilting member is in the closed position, the rear-facing camera faces the base and aligns with the aperture so that a picture can be taken.

In accordance with another embodiment, the electronic device includes a software-implemented timing function which selectively controls operation of the rear-facing camera.

In accordance with another embodiment, the tilting member is connected to the base by a hinge which retains the tilting member in a desired angular relationship with the base. In accordance with another embodiment, the base has a first end, an opposite second end; and a midpoint therebetween. The hinge is disposed between the first end and the midpoint.

In accordance with another embodiment, the screen of the tilting member is a touchscreen. In accordance with another embodiment, the input area is one of (1) a touchscreen, and (2) a hard keyboard.

In accordance with another embodiment, the electronic device is a tablet computer.

Other possible embodiments, in addition to the possible embodiments enumerated above, will become apparent from the following detailed description, taken in conjunction with the accompanying drawings, which illustrate, by way of example, the principles of the electronic device and method of use.

### BRIEF DESCRIPTION OF THE DRAWINGS

FIG. 1 is an end elevation view of an electronic device in a closed position;

FIG. 2 is a front elevation view of the electronic device in the closed position;

FIG. 3 is a side elevation view of the electronic device in the closed position;

FIG. 4 is a rear elevation view of the electronic device in the closed position;

FIG. 5 is a perspective view of the electronic device in the closed position;

FIG. 6 is a side elevation view of the electronic device in an open position;

FIG. 7 is a perspective view of the electronic device in the open position;

FIG. 8 is a front elevation view of the electronic device with a hard keyboard; and,

FIG. 9 is a side elevation view showing another embodiment of the electronic device.

### DETAILED DESCRIPTION OF THE INVENTION

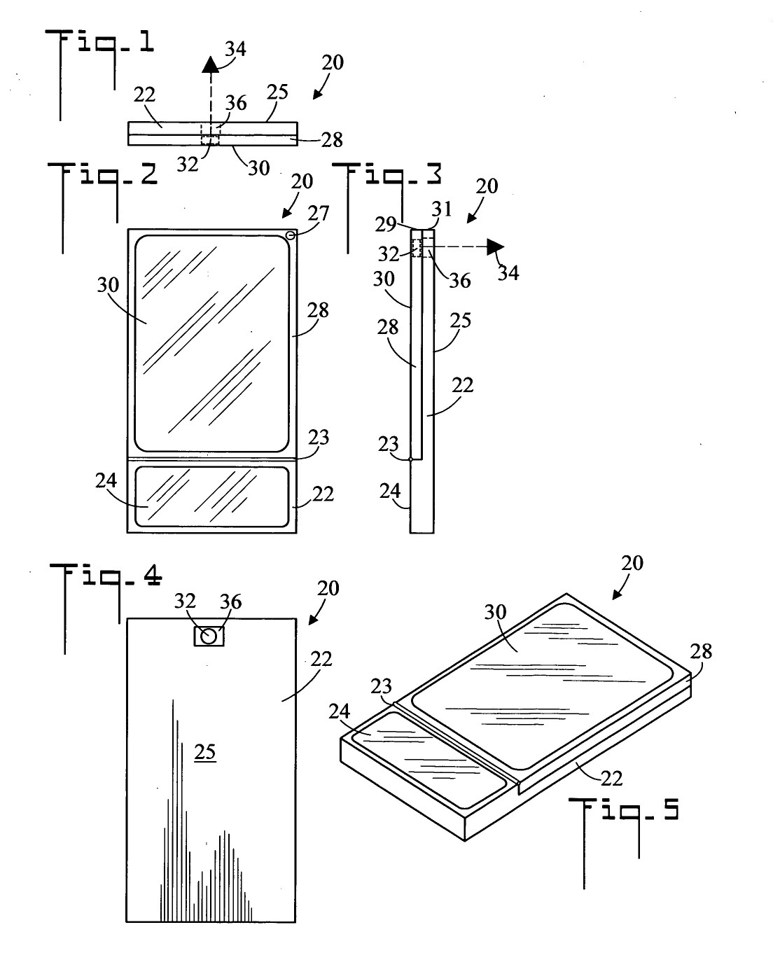

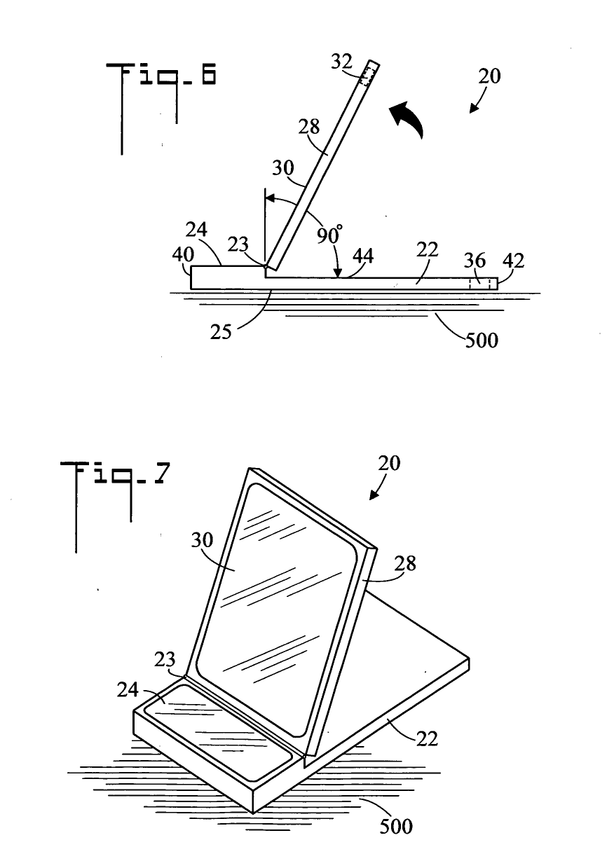

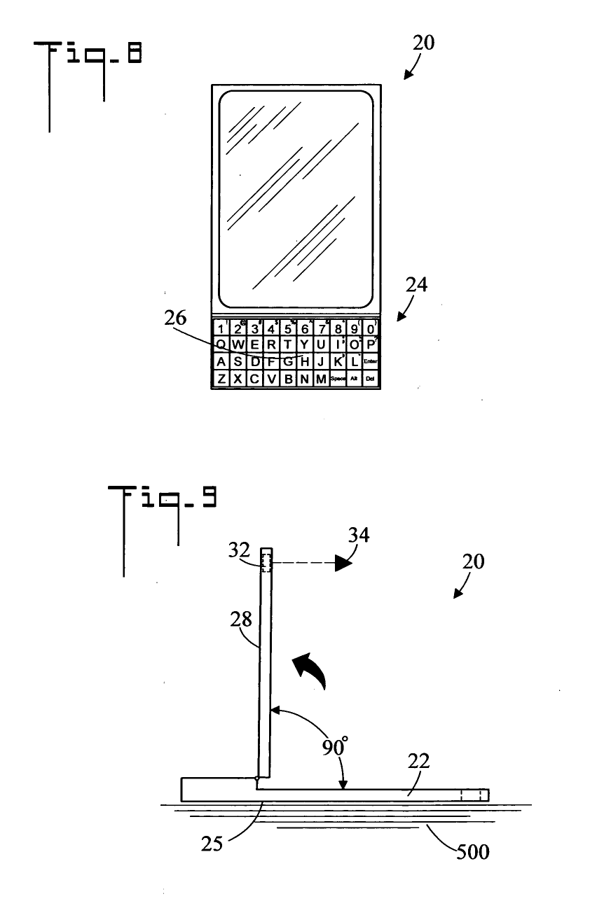

Referring initially to FIGS. 1-5, there are illustrated end elevation, front elevation, side elevation, rear elevation, and perspective views respectively of an electronic device, generally designated as 20. In FIGS. 1-6 electronic device 20 is shown in a closed position. FIGS. 6-7 show electronic device 20 in an open position. In an embodiment electronic device 20 is a tablet computer. Electronic device has a base 22 having a rear surface 25. An input area 24 is disposed on base 22, which allows a user to provide inputs to electronic device 20. In the shown embodiment, input area 24 is a touchscreen. However, input area 24 could also include a hard keyboard 26 (refer to FIG. 8). Electronic device 20 further includes a tilting member 28 which is rotationally connected to base 22 by a hinge 23. In the shown embodiment, base 22 and tilting member 28 are both rectangular in shape. A screen 30 is disposed on tilting member 28. In an embodiment, screen 30 of tilting member 28 is a touchscreen. Tilting member 28 is selectively rotatably positionable to (1) a closed position parallel to said base (refer to FIGS. 1-5), and (2) an open position upwardly angled away from base 22 (refer to FIGS. 6-7). It is noted that when tilting member 28 is in the closed position of FIGS. 1-5, input area 24 and screen 30 reside in side-by-side coplanar relationship. Also in the closed position, it is noted that distal end 29 of tilting member 28 aligns with end 31 of base 22. Typically when tilting member 28 is in the closed position, electronic device 20 is used in a handheld mode.

Tilting member 28 has a first side and an opposite second side. Screen 30 is disposed on the first side of tilting member 30, and a rear-facing camera 32 is disposed on the opposite second side of tilting member 28. That is, the lens of rear-facing camera 32 is directed away from screen 30 in the direction of arrow 34. An aperture 36 is disposed in base 22, so that when tilting member 28 is in the closed position of FIGS. 1-5, rear-facing camera 32 faces base 22 and aligns with aperture 36. As so positioned, rear-facing camera 32 can be used to take pictures when tilting member 28 is in the closed position. In addition to rear-facing camera 32, electronic device 20 also includes a front-facing camera 27 (refer to FIG. 2) which is disposed adjacent to screen 30. Front-facing camera 27 can be used to take pictures of the person using electronic device 20 such is for a video conference.

FIGS. 6 and 7 are side elevation and perspective views respectively of electronic device 20 with tilting member 28 in the open position. Electronic device 20 is positionable on a support surface 500 with rear surface 25 abutting support surface 500. In this position rear surface 25 alone supports and stabilizes tilting member 28. That is, no support arms, kick stands, extensions, props, docks, or additional mechanical members of any kind are required to support. tilting member 28—only rear surface 25 of base 22 is required. In the shown embodiment, tilting member 28 is connected to base 22 by hinge 23 which retains tilting member 28 in a desired angular relationship with base 22 (such as through angular friction). Tilting member 28 may be positioned by the user to a desired viewing angle as shown. In an embodiment, the viewing angle can be anywhere between about 0° and about 90°.

It is further noted that base 22 has a first end 40, an opposite second end 42; and a midpoint 44 therebetween. Hinge 43 is disposed between said first end 40 and midpoint 44 (about equidistant from first end 40 and midpoint 44 in the shown embodiment). FIGS. 6 and 7 also show input area 24 and screen 30. Tilting member 28 of electronic device 20 has been placed in the open position, and rear surface 25 of base 22 is placed upon a support surface 500 such as a table or desk. In this configuration electronic device 20 may be used in a “hands off” mode like a laptop computer.

FIG. 8 is a front elevation view of electronic device 20 with a hard keyboard 26 (as opposed to the touchcreen of FIGS. 1-7) which serves as input area 24. Hard keyboard is comprised of a plurality of individual keys such as on a conventional computer keyboard.

FIG. 9 is a side elevation view showing another embodiment of electronic device 20. In this embodiment electronic device 20 includes a software-implemented timing function which selectively controls operation of rear-facing camera 32. The software-controlled timing function can be used to cause rear-facing camera 32 to take a picture after a set delay (e.g. a self portrait), to take a picture at periodic intervals (e.g. every 5 minutes), to take a video for a desired period, etc. Using this timing function electronic device 20 becomes a multi-functioned tripod camera. Placing tilting screen 28 at an angle of about 90° is useful for this purpose

In terms of use, a method for using an electronic device includes: (refer to FIGS. 1-9)

(a) providing an electronic device 20 including;
a base 22 having a rear surface 25;
a input area 24 disposed on base 22;
a tilting member 28 rotationally connected to base 22;
a screen 30 disposed on tilting member 28;
wherein tilting member 28 is selectively rotatably positionable to (1) a closed position parallel to base 22, and (2) an open position upwardly angled away from base 22;

(b) providing a support surface 500; and,

(c) either (1) placing rear surface 25 on support surface 500 and then placing tilting member 28 in the open position and using electronic device 20, wherein rear surface 25 alone supports tilting member 28, or (2) with tilting member 28 in the closed position, grasping base 22 and using electronic device 20.

The method further including:

in step (a), when tilting member 28 is in the closed position, input area 24 and screen 30 reside in side-by-side coplanar relationship.

The method further including:

in step (a), tilting member 28 having a first side and an opposite second side;

in step (a), screen 30 disposed on the first side of tilting member 28;

in step (a), a rear-facing camera 32 is disposed on the second side of tilting member 28;

in step (a), an aperture 36 is disposed in base 22;

in step (a), when tilting member 28 is in the closed position, rear-facing camera 32 faces base 22 and aligns with aperture 36;

in step (c)(2), using rear-facing camera 32 to take a picture.

The method further including:

in step (b), tilting member 28 having a first side and an opposite second side;

in step (b), screen 30 disposed on the first side of tilting member 28;

in step (b), a rear-facing camera 32 disposed on the second side of tilting member 28;

in step (b), providing a software-implemented timing function which selectively controls operation of rear-facing camera 32; and,

in step (c)(1), placing tilting member 26 at a viewing angle of about 90°, and using the software-implemented timing function to control operation of rear-facing camera 32.

The method further including:

in step (a), tilting member 28 connected to base 22 by a hinge 23 which retains tilting member 28 in a desired angular relationship with base 22; and,

in step (c)(1), hinge 23 retaining tilting member 28 in the open position.

The method further including:

in step (a), base 22 having a first end 40, an opposite second end 42, and a midpoint 44 therebetween; and,

in step (a), hinge 23 disposed between first end 40 and midpoint 44.

The method further including:

in step (a), screen 30 of tilting member 28 being a touchscreen; and,

in step (c), using the touchscreen.

The method further including:

in step (a), input area 24 being one of (1) a touchscreen, and (2) a hard keyboard 26; and,

in step (c), using one of the touchscreen and the hard keyboard 26.

The method further including:

in step (a), electronic device 20 being a tablet computer.

The possible embodiments of the electronic device and method of use described herein are exemplary and numerous modifications, combinations, variations, and rearrangements can be readily envisioned to achieve an equivalent result, all of which are intended to be embraced within the scope of the appended claims. Further, nothing in the above-provided discussions of the electronic device and method should be construed as limiting the invention to a particular embodiment or combination of embodiments. The scope of the invention is best defined by the appended claims.

I claim:

1. An electronic device which is positionable on a support surface, comprising:
a base having a rear surface;
an input area disposed on said base;
a tilting member rotationally connected to said base;
a screen disposed on said tilting member;
wherein said tilting member is selectively rotatably positionable to (1) a closed position parallel to said base, and (2) an open position upwardly angled away from said base; and,
said rear surface of said base positionable on the support surface, wherein said rear surface alone supports said tilting member.

2. The electronic device according to claim 1, further including:
when said tilting member is in said closed position, said input area and said screen reside in side-by-side coplanar relationship.

3. The electronic device according to claim 1, further including:
said tilting member having a first side and an opposite second side;
said screen disposed on said first side of said tilting member;
a rear-facing camera disposed on said second side of said tilting member;
an aperture disposed in said base; and,
when said tilting member is in said closed position, said rear-facing camera faces said base and aligns with said aperture.

4. The electronic device according to claim 1, further including:
a software-implemented timing function which selectively controls operation of said rear-facing camera.

5. The electronic device according to claim 1, further including:
said tilting member connected to said base by a hinge which retains said tilting member in a desired angular relationship with said base.

6. The electronic device according to claim 5, further including:
said base having a first end, an opposite second end; and a midpoint therebetween; and,
said hinge disposed between said first end and said midpoint.

7. The electronic device according to claim 1, further including:
said screen of said tilting member being a touchscreen.

8. The electronic device according to claim 1, further including:
said input area being one of (1) a touchscreen, and (2) a hard keyboard.

9. The electronic device according to claim 1, further including:
said electronic device being a tablet computer.

10. The electronic device according to claim 1, further including:
when said tilting member is in said closed position, said input area and said screen reside in side-by-side coplanar relationship;
said tilting member having a first side and an opposite second side;
said screen disposed on said first side of said tilting member;
a rear-facing camera disposed on said second side of said tilting member;
an aperture disposed in said base;
when said tilting member is in said closed position, said rear-facing camera faces said base and aligns with said aperture;
said tilting member connected to said base by a hinge which retains said tilting member in a desired angular relationship with said base;
said base having a first end, an opposite second end; and a midpoint therebetween;
said hinge disposed between said first end and said midpoint;
said screen of said tilting member being a touchscreen;
said input area being one of (1) a touchscreen, and (2) a hard keyboard; and,
said electronic device being a tablet computer.

11. A method for using an electronic device, comprising:
(a) providing a support surface;
(b) providing an electronic device including;
a base having a rear surface;
an input area disposed on said base;
a tilting member rotationally connected to said base;
a screen disposed on said tilting member;
wherein said tilting member is selectively rotatably positionable to (1) a closed position parallel to said base, and (2) an open position upwardly angled away from said base; and,
(c) either (1) placing said rear surface of said base on said support surface and then placing said tilting member in said open position and using said electronic device, wherein said rear surface alone supports said tilting member, or (2) with said tilting member in said closed position, grasping said base and using said electronic device.

12. The method of claim 11, further including:
in step (b), when said tilting member is in said closed position, said input area and said screen reside in side-by-side coplanar relationship.

13. The method of claim 11, further including:
in step (b), said tilting member having a first side and an opposite second side;
in step (b), said screen disposed on said first side of said tilting member;
in step (b), a rear-facing camera disposed on said second side of said tilting member;
in step (b), an aperture disposed in said base;
in step (b), when said tilting member is in said closed position, said rear-facing camera faces said base and aligns with said aperture; and,
in step (c)(2), using said rear-facing camera to take a picture.

14. The method of claim 11, further including:
in step (b), said tilting member having a first side and an opposite second side;
in step (b), said screen disposed on said first side of said tilting member;
in step (b), a rear-facing camera disposed on said second side of said tilting member;
in step (b), providing a software-implemented timing function which selectively controls operation of said rear-facing camera; and,
in step (c)(1), placing said tilting member at a viewing angle of about 90°, and using said software-implemented timing function to control operation of said rear-facing camera.

15. The method according to claim 11, further including:
in step (b), said tilting member connected to said base by a hinge which retains said tilting member in a desired angular relationship with said base; and,
in step (c)(1), said hinge retaining said tilting member in said open position.

16. The method according to claim 11, further including:
in step (a), said base having a first end, an opposite second end; and a midpoint therebetween; and,
in step (b), said hinge disposed between said first end and said midpoint.

17. The method of claim 11, further including:
in step (b), said screen of said tilting member being a touchscreen; and,
in step (c), using said touchscreen.

18. The method of claim 11, further including:
in step (b), said input area being one of (1) a touchscreen, and (2) a hard keyboard; and,
in step (c), using one of said touchscreen and said hard keyboard.

19. The method of claim 11, further including:
in step (b), said electronic device being a tablet computer.
